(19) United States
(12) Patent Application Publication
(10) Pub. No.: US 2022/0358258 A1
(43) Pub. Date: Nov. 10, 2022

(54) COMPUTER-AIDED DESIGN METHODS AND SYSTEMS

(71) Applicants: Mauro SICA, Berkeley, CA (US); PRE FRAMING CORP., Berkeley, CA (US)

(72) Inventor: Mauro SICA, Berkeley, CA (US)

(21) Appl. No.: 17/765,150

(22) PCT Filed: Sep. 30, 2020
(86) PCT No.: PCT/EP2020/077294

§ 371 Date: Mar. 30, 2022

Related U.S. Application Data
(60) Provisional application No. 62/907,923, filed on Sep. 30, 2019.

(51) Int. Cl. G06F 30/12; G06T 11/20; G06F 3/04845

(52) U.S. Cl. CPC G06F 30/12; G06T 11/203; G06F 3/04845; G06T 2200/24; G06T 2210/04; G06F 2203/04806

(57) ABSTRACT

The present invention generally relates to computer-aided design or drafting (CAD) systems and, more particularly, to tools or functions in such systems for orthogonal drafting that allows users to prepare and edit CAD drawings. It comprises a computer-aided design process performed by a computer system, comprising the steps of: (a) receiving from a user an input of a start point and an end point for a polyline comprising two orthogonal line segments on a drawing; (b) automatically selecting one of two possible paths for the polyline based on existing line segments in the drawing; (c) displaying the polyline on the drawing in the path selected in step (b).

### BACKGROUND

The present invention generally relates to computer-aided design or drafting (CAD) systems and, more particularly, to tools or functions in such systems for orthogonal drafting that allows users to more quickly and efficiently prepare and edit CAD drawings.

CAD software (e.g., AutoCAD and other similar software) is a computer-implemented graphical design tool that allows users to create and edit 2-D and 3-D drawings. CAD software is used in a variety of different fields, including architecture and engineering. A user interacts with the CAD software using computer input devices (e.g., a keyboard, mouse, trackball, or stylus), with the drawing being displayed on a computer display.

### BRIEF DESCRIPTION OF THE DRAWINGS

FIGS. 1-5 are simplified drawings for illustrating use of CAD tools or functions in accordance with one or more embodiments.

FIG. 6 is a flowchart illustrating an exemplary CAD drafting process in accordance with one or more embodiments.

FIG. 7 is a simplified block diagram illustrating a representative computer system in which the CAD tools or functions can be executed.

### DETAILED DESCRIPTION

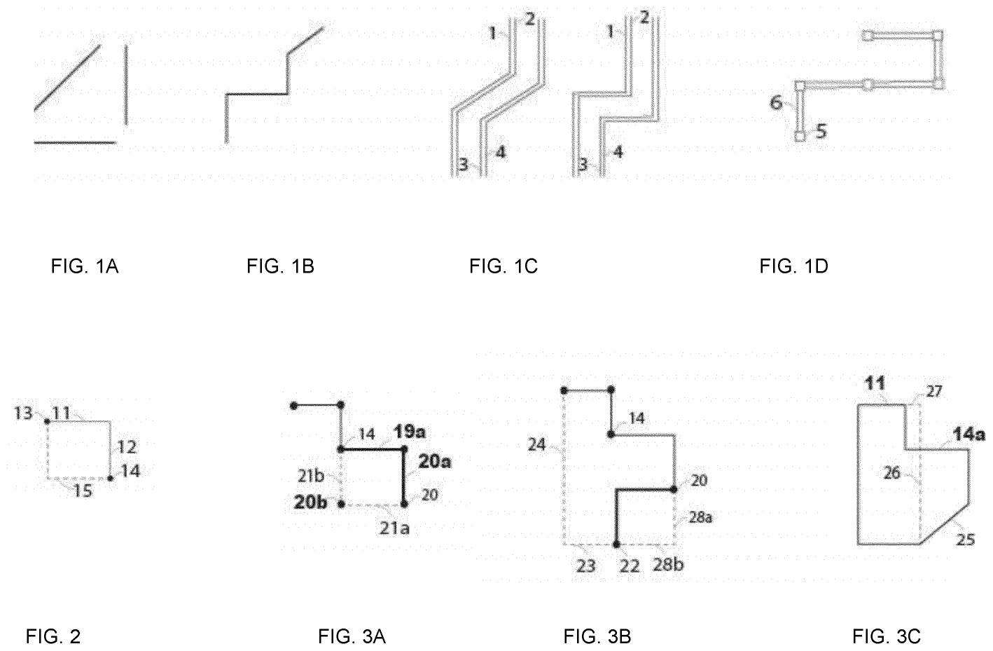

Various embodiments disclosed herein relate to CAD tools or functions that can be used to draw lines (as shown, e.g., in FIG. 1A), polylines (a series of lines connected together as shown, e.g., in FIG. 1B), or components and smart components such as walls (shown, e.g., in FIG. 1C), fences (as shown, e.g., in FIG. 1D), or generally any object with a linear layout mainly or exclusively oriented according to a perpendicular axis in 2-D or 3-D. One exemplary embodiment relates to architectural drawings, both creating new drawings and editing existing drawings, e.g., by overlapping features or objects on an existing drawing. Because those lines (FIG. 1A), polylines (FIG. 1B) and smart components (FIGS. 1C-1D) are mainly or exclusively oriented along two perpendicular axes in most applications, tools or functions disclosed herein can significantly speed up both the process of drafting over an existing drawing and creating new drawings from scratch.

In one or more embodiments, the tools or functions in accordance with various embodiments can comprise a plug-in to commercially available CAD software (e.g., AutoCAD and other similar software). Alternatively, the tools or functions can be integrated in a CAD application.

In one or more embodiments, the CAD tools or functions can be used to feed the necessary data to an apparatus able to print lines drawn by the CAD system on the subfloor or floor of a building and/or to an apparatus able to manufacture prefabricated or partially prefabricated walls. U.S. Pat. No. 10,011,981, which is assigned to the assignee of the present application, discloses methods and systems for manufacturing prefabricated or partially prefabricated walls.

The CAD tools or functions in accordance with one or more embodiments can be used in various types of computers including desktop computers, laptop and notebook computers, as well as tablet computers, smartphones, and other portable devices. In architectural applications, the tools or functions can be used to create lines, polylines, or components including smart components such as walls, fences, or any object with a linear layout, mainly or exclusively oriented according to perpendicular axes in 2-D or 3-D.

Known CAD systems allow a line or smart component to be drawn relative to a perpendicular axis. Known CAD systems allow a set of four lines to be drawn constituting a rectangle by a user clicking on two points only. Known CAD systems, however, do not draw new lines or components based on the already drawn lines and components from predictions of the most likely desired behavior. CAD tools or functions as disclosed herein can significantly reduce the time needed to accomplish a drawing task, e.g., by 50%.

Most existing CAD software requires computers with powerful graphic performance and perform poorly on the average desktop and laptop computers. In some software applications such as AutoCAD, even simply moving the mouse cursor precisely in position can be time consuming due to lagging of the positioning of the cursor due to inadequate processing power of the computer. CAD software in accordance with various embodiments can be executed on general computing devices including portable computer devices and can significantly increase user productivity.

### 2× Polyobject Function

When a user start drawing a polyline in a drawing in a conventional CAD system, the system does not have a sure way to determine which path the polyline needs to follow. Referring to FIG. 2, the user, while clicking on the two points 13 and 14 only, could simultaneously generate two segments using a function in accordance with one or more embodiments referred to herein as the “2× polyobject” function. The user might wish to draw the two segments 11 and 12 or take the alternative path 15. The system can only guess or conventionally always provide the same path option. The path can also be modified by providing some kind of input to the system, e.g., pressing a button on the computer keyboard or mouse. In this case, by pressing the button, the path will swap between the path 15 and the path 11, 12.

Alternatively, the computer system could automatically disable the 2× polyobject function for the first two segments. In this case, the user will need to draw the segment 11 first and the segment 12 later, with a total of three clicks determining the segment end points.

Once the first two segments are drafted, the system will use those as reference to univocally (i.e., unambiguously) determine the path of the segments or lines.

Referring to FIG. 3A, after the user moves the mouse from the previous end point 14 to point 20 and clicks on the point 20, the system will intelligently determine that the wanted path can only be the one where the first of the two segments (14a) is perpendicular to the last one drafted (12), thereby disregarding the possible path made of the segment 21a and 21b. It is assumed that if the user wanted to go to point 20b, the user would have clicked on point 20b instead of point 14 in the first place.

Similarly, once the user clicks on point 22 (in FIG. 3B) from the point 20, the only wanted path will be determined by the system to be the one illustrated in the drawing; the system disregards possible path 28a/28b.

If the user, during the drafting of the 2× polyobject, wishes to draw a segment not orthogonal (i.e., 0, 90, 180, 270 degrees), he or she can simply disable the function, e.g., with a control key on the keyboard or the mouse (or touching the screen, or opening a menu). The user can then, for instance, draft the segment 25.

Referring to FIG. 3C, once the 2× polyobject function is re-enabled, the user could close the polyline or poly-object by pressing another control key, e.g., “Enter” or “c”. Again, the system will be able to determine univocally where to go, discarding the possible path 26, because the path 26 will overwrite and cross existing segments, in this case overdrawing a portion of the starting segment 11 and crossing the segment 14a.

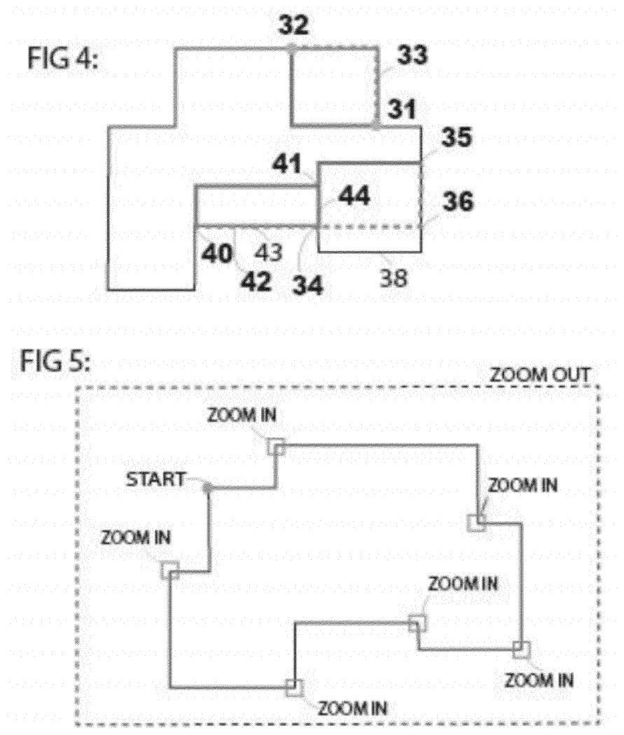

Moving forward, referring to FIG. 4, once the polyline or poly-object 38 has been created, in this example representing exterior walls of a building, the user might want now to draw, using the same 2× polyobject function, polylines or polyobjects representing interior walls.

If, for instance, the user wanted to close a section of the drawing, representing a room starting from point 31 and clicking on point 32, the system will, again, using all the previous drafted segments already drafted, determine univocally the intention of the user. The system will draft the polyline and avoiding the path 33 (dashed polyline) because it overlaps two existing segments.

If the user wanted to close a section of the drawing representing a room (polyline 44) starting from point 34 and clicking on point 35, the system will determine univocally the intention of the user, and draft the polyline 44, disregarding the possible path 36 (dashed polyline).

If the user wanted to close a section of the drawing representing another room starting from point 40 and clicking on point 41, the system will determine univocally the intention of the user, and draft the polyline and disregard the possible path 42 (dashed polyline).

In this way, the 2× polyobject function minimizes user actions needed to accomplish a drawing task and thereby allows users to significantly reduce the time needed to complete tasks.

FIG. 6 is a flowchart illustrating an exemplary 2× polyobject function process in accordance with one or more embodiments.

### Instant Zoom Function

In accordance with one or more additional embodiments, the CAD system includes an instant zoom function that further reduces the time needed to complete drawing tasks.

Zooming in and out, or performing a panning operation needed to precisely hit a given point in overwriting a drawing can take a significant amount of time, especially when using standard computers with limited processing power.

The instant zoom function in accordance with one or more embodiments solves this problem. When beginning the drafting of the polyline or poly-object using the 2× polyobject function, the computer system determines the level of zoom (1×) and memorize it.

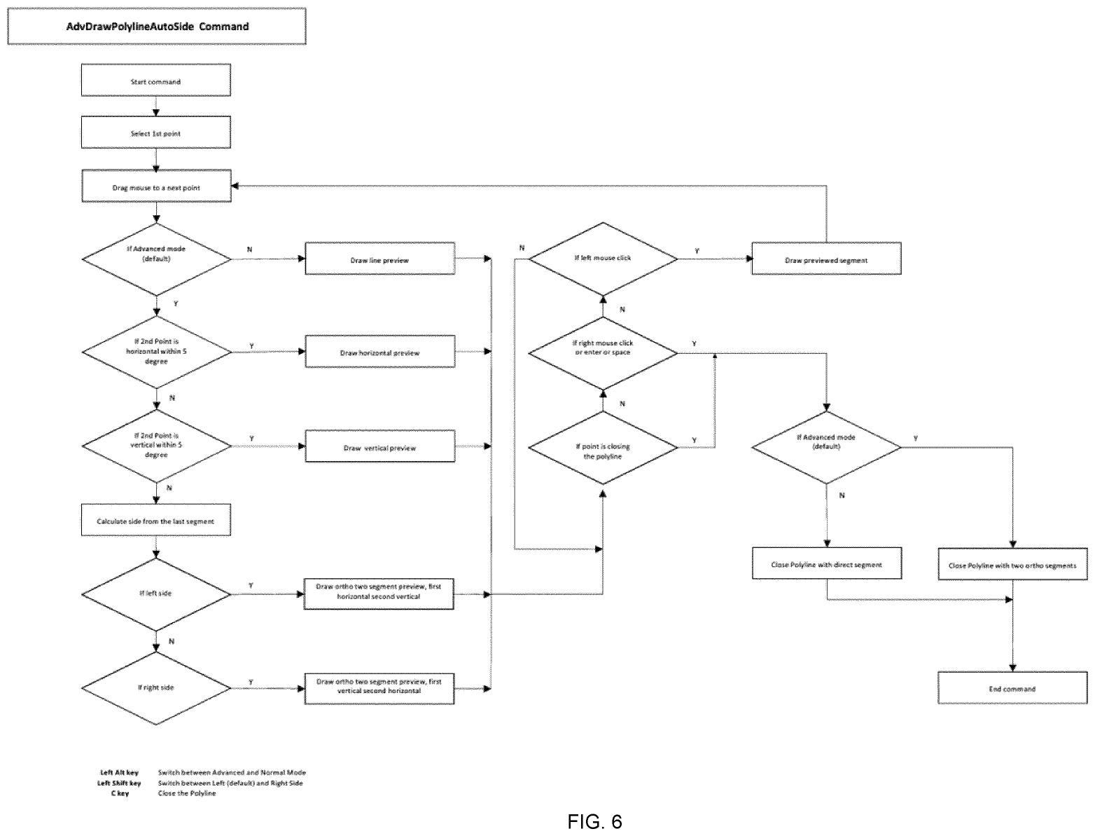

Every time the user needs to zoom in, to snap or click precisely on a particular point as shown in FIG. 5, the user can activate the function by, e.g., simply pressing a control button on the keyboard or on the mouse to zoom in by a predetermined factor (e.g., 5×).

If the user is not satisfied with the level of zoom, the user can further zoom in, using the commonly used controls, e.g., the mouse wheel. The computer system can “learn” from the behavior of the user and adjust the level of zoom for the next time the instant zoom function will be called (e.g., 7×).

Once the user clicks on the point, while the system is in zoom in mode, the computer system will zoom out automatically to the initial level (1×) when the command 2× polyobject was started.

The user can then move quickly and effectively on the next point and zoom in again using the instant zoom function.

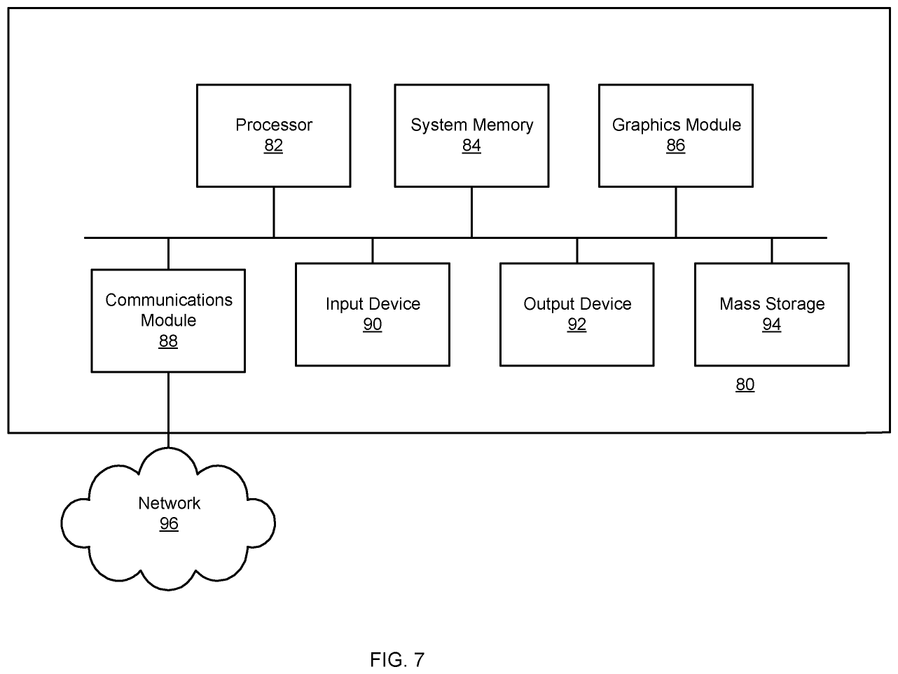

The methods, operations, modules, and systems described herein may be implemented in one or more computer programs executing on a programmable computer system. FIG. 7 is a simplified block diagram illustrating an exemplary computer system 80, on which the computer programs may operate as a set of computer instructions. The computer system 80 includes at least one computer processor 82, system memory 84 (including a random access memory and a read-only memory) readable by the processor 82. The computer system 80 also includes a mass storage device 94 (e.g., a hard disk drive, a solid-state storage device, an optical disk device, etc.). The computer processor 82 is capable of processing instructions stored in the system memory or mass storage device. The computer system 80 additionally includes input/output devices 90, 92 (e.g., a display, keyboard, pointer device, etc.), a graphics module 86 for generating graphical objects, and a communication module or network interface 88, which manages communication with other devices via telecommunications and other networks 96.

Each computer program can be a set of instructions or program code in a code module resident in the random access memory 84 of the computer system 80. Until required by the computer system 80, the set of instructions may be stored in the mass storage device 94 or on another computer system and downloaded via the Internet or other network.

Having thus described several illustrative embodiments, it is to be appreciated that various alterations, modifications, and improvements will readily occur to those skilled in the art. Such alterations, modifications, and improvements are intended to form a part of this disclosure, and are intended to be within the spirit and scope of this disclosure. While some examples presented herein involve specific combinations of functions or structural elements, it should be understood that those functions and elements may be combined in other ways according to the present disclosure to accomplish the same or different objectives. In particular, acts, elements, and features discussed in connection with one embodiment are not intended to be excluded from similar or other roles in other embodiments.

Additionally, elements and components described herein may be further divided into additional components or joined together to form fewer components for performing the same functions. For example, the computer system may comprise one or more physical machines, or virtual machines running on one or more physical machines. In addition, the computer system may comprise a cluster of computers or numerous distributed computers that are connected by the Internet or another network.

Accordingly, the foregoing description and attached drawings are by way of example only, and are not intended to be limiting.

1. A computer-aided design (CAD) process performed by a computer system, comprising the steps of:
(a) receiving from a user an input of a start point and an end point for a polyline comprising two orthogonal line segments on a drawing;
(b) automatically selecting one of two possible paths for the polyline based on existing line segments in the drawing;
(c) displaying the polyline on the drawing in the path selected in step (b).

2. A computer-aided design (CAD) process performed by a computer system, comprising the steps of:
(a) displaying a drawing to a user on a computer display at a predetermined zoom level;
(b) receiving a pointer input from the user pointing to a particular location on the drawing;
(c) receiving an input from the user to activate an instant zoom function; and
(d) increasing the zoom level at the particular location of the drawing by a predetermined factor in response to the input received in step (c).

3, A computer-aided design (CAD) process performed by a computer system, comprising the steps of:
(a) receiving from a user an input of a start point and an end point for a polyobject comprising two orthogonal segments of a linear object or polyobject on a drawing, where the said two linear object segments coincide with two subsequent sides of a rectangular shaped object, said rectangular shaped object being identified by its diagonal, as defined by the start and end points clicked by the user;
(b) automatically disabling a 2× polyobject function for the first two segments, or, alternatively, allowing the user to pick of the two possible paths of the orthogonal linear object segments, by providing an input to the system, e.g., pressing a button on the computer keyboard or mouse, in order to alternatively swap between the two possible combination of orthogonal linear object segments;
(c) displaying a dynamic preview of the linear object segments or polyobject on the screen before permanently drawing it on the screen, in the path determined using the previous steps;
(d) determining the path of the subsequent segments of polyobjects, whenever two segments of a polyobject are drafted, wherein in said subsequent path the first of the subsequent at least two segments (14a) is perpendicular to the last drafted segment, discarding the path where the first of the at least two segments would constitute an extension of the last polyobject segment of the previous polyobject segment already drawn.
(e) displaying a dynamic preview of the the linear object segments or polyobject on the screen, then permanently draw it on the screen, in the path determined using the previous steps.

4. A computer-aided design (CAD) process performed by a computer system according to claim 3, including the step of temporarily disabling the said “2× polyobject” function when the user, during the drafting, wishes to draw a segment not orthogonal, such as a diagonal segment.

5. A computer-aided design (CAD) process performed by a computer system according to claim 3, wherein when said “2× polyobject” function is enabled, the process includes the step of adding the remaining two polyobject segments necessary to close the polyobject by pressing another control key, univocally determining the path to take, discarding any possible path which overdraws or cross existing, previously drafted polyobject segments.

6. A computer-aided design (CAD) process performed by a computer system according to claim 3, comprising the steps of:
(a) receiving from a user an input of a start point and an end point for a polyobject comprising two orthogonal linear object segments on a drawing, being the points located directly onto or inside a closed polyobject previously created, for instance polyobjects such as polylines, representing interior walls inside an existing closed polyobjects representing the exterior walls;
(b) univocally and automatically determining, whenever two segments of a polyobject such as a polyline are already drafted, the wanted path, which is the one that does not overdraws or crosses one or more existing orthogonal segments or a portion of them (for instance the path 33 represented by a dashed line is discarded because would overdraw the existing closed polyline) or, alternatively, once at least two linear object segments are already drafted inside an existing closed polyobject, automatically selecting a path where the first of the two segments (14a) is perpendicular to the last segment drafted;
(c) displaying a dynamic preview of the polyobject on the screen, then permanently draw it on the screen, in the path determined using the previous steps.

7. A computer-aided design (CAD) process performed by a computer system according to claim 3, where the polyobject is a polyline, a component, or smart components such as walls, fences, which may also include subcomponents, such as fence posts, wall studs, opening studs, windows or door components or sub-segments of lines of different kind.

8. A computer-aided design (CAD) process performed by a computer system according to claim 3, wherein operations, modules, and systems are implemented in one or more computer programs executing on a programmable computer system, wherein said computer programs may operate as a set of computer instructions.

9. A computer aided process according to claim 8, wherein the computer system includes at least one computer processor, a system memory, including a random access memory and a read-only memory, readable by said processor, a mass storage device in which the computer processor is capable of processing instructions stored in the system memory or mass storage device, and wherein said computer system additionally includes input/output devices, a graphics module for generating graphical objects, and a communication module or network interface, which manages communication with other devices via telecommunications and/or other networks.
